(19) United States
(12) Patent Application Publication
(10) Pub. No.: US 2018/0090451 A1
(43) Pub. Date: Mar. 29, 2018

(54) SEMICONDUCTOR DEVICE AND MANUFACTURING METHOD OF THE SAME

(71) Applicant: Renesas Electronics Corporation, Tokyo (JP)

(72) Inventors: Yoshihisa MATSUBARA, Ibaraki (JP); Yasuhiro SHIMADA, Ibaraki (JP); Yoshitaka KYOUGOKU, Tokyo (JP)

(21) Appl. No.: 15/655,831

(22) Filed: Jul. 20, 2017

(30) Foreign Application Priority Data
Sep. 28, 2016 (JP) 2016-189362

(51) Int. Cl. H01L 23/00; H01L 23/498; H01L 21/48

(52) U.S. Cl. CPC H01L 23/562; H01L 24/16; H01L 23/49822; H01L 23/49827; H01L 23/49838; H01L 2224/16227; H01L 23/49894; H01L 23/49866; H01L 21/4857; H01L 21/486; H01L 21/4853; H01L 23/49877

(57) ABSTRACT

While strength of a wiring board in a semiconductor substrate is ensured, thermal conductivity is increased. A BGA includes a wiring board having an upper surface and a lower surface, a semiconductor chip mounted on the upper surface of the wiring board, and ball electrodes that are a plurality of external terminals provided on the lower surface of the wiring board. The wiring board includes an insulation layer arranged between wiring layers. The insulation layer includes a resin layer, another resin layer, and an electrically conducting layer arranged between the resin layer and the other resin layer. The electrically conducting layer is formed by a lamination of a graphite sheet and a metal layer.

### CROSS-REFERENCE TO RELATED APPLICATIONS

The disclosure of Japanese Patent Application No. 2016-189362 filed on Sep. 28, 2016 including the specification, drawings and abstract is incorporated herein by reference in its entirety.

### BACKGROUND

The present invention relates to a semiconductor device and a manufacturing technique of the same. For example, the present invention relates to a technique that is effectively applied to a semiconductor device in which a semiconductor chip is mounted on a wiring board.

A semiconductor device configured to include a semiconductor chip mounted on a wiring board, which requires heat dissipation, requires measures in order to increase thermal conductivity of the wiring board, because the wiring board is formed mainly of a resin.

For example, Japanese Unexamined Patent Application Publication No. 2011-166029 describes a structure of a wiring board that includes a first insulation layer, a second insulation layer, and a graphite sheet sandwiched between the first insulation layer and the second insulation layer.

### SUMMARY

The graphite sheet, which is described in Japanese Unexamined Patent Application Publication No. 2011-166029 as being sandwiched between resin layers, is good in thermal conduction in a planar direction. In particular, the graphite sheet has a high thermal conductivity when its thickness is less than 40 μm.

However, the graphite sheet is significantly low in softening resistance in the planar direction when it is thin. That is, there is a problem that the graphite sheet is weak against stress in a vertical direction and therefore can be easily bent, while being strong against stress in the planar direction.

Other problems and novel features will be apparent from the description of this specification and the accompanying drawings.

A semiconductor device according to an embodiment includes a wiring board having a first surface and a second surface, a semiconductor chip mounted on the first surface of the wiring board, and a plurality of external terminals provided on the second surface of the wiring board. The wiring board includes a first wiring layer, a second wiring layer arranged over the first wiring layer, a first insulation layer arranged between the first wiring layer and the second wiring layer, a second insulation layer formed in a first hole extending through the first insulation layer, and a conductor portion that is formed in a second hole extending through the second insulation layer and electrically couples a wiring of the first wiring layer and a wiring of the second wiring layer to each other. Further, the first insulation layer includes a first resin layer, a second resin layer, and an electrically conducting layer arranged between the first resin layer and the second resin layer. The electrically conducting layer is formed by a lamination of a graphite sheet and a metal layer.

A manufacturing method of a semiconductor device according to an embodiment includes the steps of (a) forming a first wiring layer over a supporting substrate, (b) after the step (a), forming a first insulation layer including a first resin layer, a second resin layer, and an electrically conducting layer arranged between the first resin layer and the second resin layer over the first wiring layer, and (c) after the step (b), forming a first hole extending through the first insulation layer. Further, the manufacturing method includes the steps of (d) after the step (c), forming a second insulation layer in the first hole, (e) after the step (d), forming a second hole extending through the second insulation layer, and (f) after the step (e), forming a conductor portion in the second hole. The manufacturing method further includes the steps of (g) after the step (f), forming a second wiring layer over the first insulation layer and electrically coupling a wiring of the first wiring layer and a wiring of the second wiring layer to each other by the conductor portion in the second hole, and (h) after the step (g), separating the supporting substrate and the first wiring layer to form a wiring board having a first surface and a second surface. The manufacturing method further includes the steps of (i) after the step (h), mounting a semiconductor chip over the first surface of the wiring board, and (j) after the step (i), providing an external terminal for each of a plurality of electrodes in the first wiring layer. The electrically conducting layer is a lamination of a graphite sheet and a metal layer.

According to the embodiment, it is possible to increase thermal conductivity while strength of a wiring board in a semiconductor device is ensured.

### BRIEF DESCRIPTION OF THE DRAWINGS

FIG. 1 is a cross-sectional view illustrating a structure example of a semiconductor device according to a first embodiment.

FIG. 2 is a line chart illustrating examples of a relation between a graphite ratio and a thermal conductivity when various metal materials are used.

FIG. 3 includes partial cross-sectional views illustrating an example of manufacturing steps of a wiring board incorporated in the semiconductor device illustrated in FIG. 1.

FIG. 4 includes partial cross-sectional views illustrating an example of manufacturing steps of the wiring board incorporated in the semiconductor device illustrated in FIG. 1.

FIG. 5 includes partial cross-sectional views illustrating an example of manufacturing steps of the wiring board incorporated in the semiconductor device illustrated in FIG. 1.

FIG. 6 includes partial cross-sectional views illustrating an example of manufacturing steps of the wiring board incorporated in the semiconductor device illustrated in FIG. 1.

FIG. 7 includes partial cross-sectional views illustrating an example of manufacturing steps of the wiring board incorporated in the semiconductor device illustrated in FIG. 1.

FIG. 8 is a partial cross-sectional view illustrating an example of a manufacturing step of the wiring board incorporated in the semiconductor device illustrated in FIG. 1.

FIG. 9 is a partial cross-sectional view illustrating an example of a manufacturing step of the wiring board incorporated in the semiconductor device illustrated in FIG. 1.

FIG. 10 is a partial cross-sectional view illustrating an example of a manufacturing step of the wiring board incorporated in the semiconductor device illustrated in FIG. 1.

FIG. 11 is a partial cross-sectional view illustrating an example of a step of mounting a semiconductor chip on the wiring board illustrated in FIG. 10.

FIG. 12 is a partial cross-sectional view illustrating an example of a mounting structure of the semiconductor device illustrated in FIG. 1.

FIG. 13 includes partial cross-sectional views illustrating an example of manufacturing steps of a core substrate according to a second embodiment.

FIG. 14 includes partial cross-sectional views illustrating an example of manufacturing steps of the core substrate according to the second embodiment.

FIG. 15 is a partial cross-sectional view illustrating an example of a manufacturing step of the core substrate according to the second embodiment.

FIG. 16 is a partial cross-sectional view illustrating a structure of an electrically conducting layer in a modified example.

FIG. 17 is a partial cross-sectional view illustrating a structure of an electrically conducting layer in another modified example.

### DETAILED DESCRIPTION

In the following embodiments, the description of the same or similar portions are not repeated in principle, unless otherwise necessary.

The following embodiment will be described while being divided into a plurality of sections or embodiments, if necessary for the sake of convenience. However, unless otherwise specified, these are not independent of each other, but are in a relation such that one is a modification example, details, complementary explanation, or the like of a part or the whole of the other.

In the following embodiments, when a reference is made to the number of elements and the like (including number, numerical value, quantity, range, or the like), the number of elements is not limited to the specific number, but may be the specific number or more or the specific number or less, unless otherwise specified, or except the case where the number is apparently limited to the specific number in principle, or except for other cases.

Further, in the following embodiments, the constitutional elements (including element steps or the like) are not always essential, unless otherwise specified, or except the case where they are apparently considered essential in principle, or except for other cases.

Furthermore, in the following embodiments, phrases “include A”, “be formed by A”, “have A”, and “contain A” are not intended to exclude a constitutional element other than A, except the case where it is clearly described that a constitutional element is only A. Similarly, in the following embodiments, when a reference is made to the shapes, positional relationships, or the like of the constitutional elements or the like, it is understood that they include ones substantially analogous or similar to the shapes or the like, unless otherwise specified, or unless otherwise considered apparently in principle, or except for other cases. This also applies to the foregoing numerical value, range, or the like.

Embodiments are described in detail below, referring to the drawings. Throughout the drawings for explaining the embodiments, members having the same functions are labeled with the same reference signs and the redundant description thereof is omitted. Further, hatching may be added even in a plan view in order to make the drawings easier to understand.

### First Embodiment

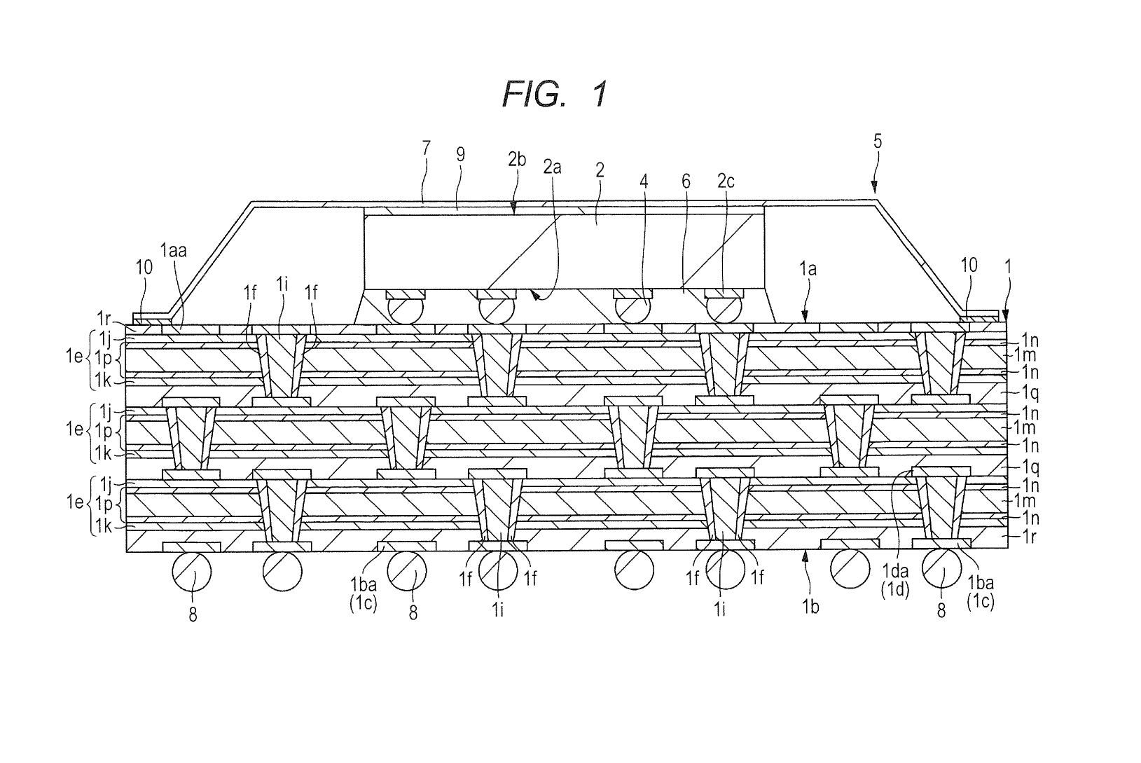

FIG. 1 is a cross-sectional view illustrating a structure example of a semiconductor device according to a first embodiment.

The semiconductor device of this first embodiment illustrated in FIG. 1 is a heat-dissipation type semiconductor package in which a semiconductor chip is mounted on a wiring board by flip-chip mounting and a lid member called a lid is further provided on the semiconductor chip to cover the semiconductor chip.

In this first embodiment, a case is described as an example of the above semiconductor device, in which external terminals of the above semiconductor device are a plurality of ball electrodes provided on a lower surface of the wiring board. Therefore, the semiconductor device of this first embodiment is also a BGA (Ball Grid Array).

Referring to FIG. 1, the structure of a BGA 5 in this first embodiment is described. The BGA 5 includes a wiring board 1 having an upper surface (a first surface) 1a and a lower surface (a second surface) 1b opposite to the upper surface 1a, a semiconductor chip 2 mounted on the upper surface 1a of the wiring board 1, and ball electrodes 8 that are a plurality of external terminals provided on the lower surface 1b of the wiring board 1.

The semiconductor chip 2 is flip-chip mounted on the upper surface 1a of the wiring board 1 via a plurality of bump electrodes 4. A lid 7 is provided to cover the semiconductor chip 2. The semiconductor chip 2 has a main surface 2a and a back surface 2b opposite to the main surface 2a. A plurality of electrode pads 2c are formed on the main surface 2a.

The upper surface 1a of the wiring board 1 has a plurality of lands (terminals, electrodes) 1aa provided thereon, while the lower surface 1b also has a plurality of lands (terminals, electrodes) 1ba provided thereon. A solder resist film (an insulation film) 1r is formed on a surface on each of the upper surface 1a side and the lower surface 1b side. In each of a plurality of openings in the solder resist film 1r on each of the upper surface 1a side and the lower surface 1b side is exposed the land 1aa on the upper surface 1a side or the land 1ba on the lower surface 1b side.

The semiconductor chip 2 is mounted on the upper surface 1a of the wiring board 1 by flip-chip mounting. More specifically, the main surface 2a of the semiconductor chip 2 is arranged to be opposed to the upper surface 1a of the wiring board 1, and is electrically coupled to the lands 1aa on the upper surface 1a of the wiring board 1 via a plurality of bump electrodes (bumps, projecting electrodes) 4.

The ball electrodes 8 that are the external terminals are provided on the lower surface 1b side of the wiring board 1 to be arranged in a grid (a lattice), for example.

With the above structure, in the BGA 5, the electrode pads 2c of the semiconductor chip 2 mounted on the upper surface 1a of the wiring board 1 are electrically coupled to the ball electrodes 8 on the lower surface 1b side of the wiring board 1 via the bump electrodes 4, the lands 1aa, and the lands 1ba that correspond to the electrode pads 2c, respectively. An internal structure of the wiring board 1 will be described in detail later.

Also, in the BGA 5, a space between the semiconductor chip 2 and the wiring board 1 is filled with an underfill (a resin, an adhesive) 6. That is, spaces between the bump electrodes 4 are filled with the underfill 6. Therefore, a difference of a coefficient of thermal expansion between the semiconductor chip 2 and the wiring board 1 is buffered by the underfill 6. That is, it is possible to reinforce a flip-chip bonding portion of the semiconductor chip 2 by the underfill 6.

Further, in the BGA 5 of this first embodiment, the semiconductor chip 2 is covered by the lid 7 made of metal in order to enhance a head dissipation function of the semiconductor chip 2.

For example, the lid 7 is formed by a metal plate, for example, a copper plate. The lid 7 is bonded to the back surface (the surface facing up) 2b of the semiconductor chip 2 via an electrically conducting adhesive 9.

For example, the electrically conducting adhesive 9 is a silver paste or an aluminum-based paste.

With this bonding of the semiconductor chip 2 and the lid 7 formed by the metal plate via the electrically conducting adhesive 9, it is possible to dissipate heat generated from the semiconductor chip 2, from the lid 7 through the electrically conducting adhesive 9, thus improving reliability of the BGA 5.

An adhesive 10 bonding the lid 7 and the wiring board 1 to each other is an epoxy resin-based adhesive 10, for example.

Next, a detailed structure of the wiring board 1 incorporated in the BGA 5 is described.

The wiring board 1 illustrated in FIG. 1 is a multilayered wiring board including multiple wiring layers, is a coreless substrate, and is also a build-up substrate formed by stacking a prepreg layer and a wiring layer.

The wiring board 1 includes a wiring layer (a first wiring layer) 1c, a wiring layer (a second wiring layer) 1d arranged on the wiring layer 1c, and an insulation layer (a first insulation layer) 1e arranged between the wiring layer 1c and the wiring layer 1d. The wiring board 1 further includes an insulation layer (a second insulation layer) 1f formed in a hole (a first hole) 1g extending through the insulation layer 1e illustrated in FIG. 10 described later, and a via wiring (a conductor portion) 1i that is formed in a hole (a second hole) 1h extending through the insulation layer 1f and electrically couples the land 1ba of the wiring layer 1c and a land 1da of the wiring layer 1d in FIG. 1 to each other.

The insulation layer 1e includes a resin layer (a first resin layer) 1j, a resin layer (a second resin layer) 1k, and an electrically conducting layer 1p arranged between the resin layer 1j and the resin layer 1k. The electrically conducting layer 1p is formed by a lamination of a graphite sheet 1m and a metal layer 1n.

That is, the electrically conducting layer 1p formed by the lamination of the graphite sheet 1m and the metal layer 1n is sandwiched between the resin layer 1j and the resin layer 1k.

Further, in the wiring board 1 of this first embodiment, the electrically conducting layer 1p is a lamination in which the graphite sheet 1m is sandwiched between the metal layers 1n, so that the electrically conducting layer 1p has a three-layered structure of the graphite sheet 1m and the metal layers 1n arranged above and below the graphite sheet 1m.

That is, a plurality of insulation layers 1e each including the electrically conducting layer 1p formed by the graphite sheet 1m and the metal layers 1n are formed in the wiring board 1. A resin layer 1q that is a third resin layer is formed between the insulation layers 1e.

The graphite sheet 1m is electrically conductive. Therefore, the via wiring 1i that extends through the insulation layer 1e including the electrically conducting layer 1p and electrically couples the land 1ba of the wiring layer 1c and the land 1da of the wiring layer 1d to each other is covered in its surroundings in a planar direction by the insulation layer 1f that is the second insulation layer and is a resin column. That is, each of the via wirings 1i is covered by the insulation layer 1f in its surroundings in the planar direction. With this structure, insulation between the via wirings 1i and the electrically conducting layer 1p is ensured.

In the wiring board 1 of this first embodiment, the graphite sheet 1m is arranged in order to improve a thermal conductivity of the wiring board 1. Here, the structure of graphite is described. Graphite has a stacking structure of large planar molecules in each of which benzene rings are arranged in a plane and each of which is called a graphene sheet. Graphene is a single layer of carbon atoms thickly packed in a two-dimensional honeycomb grid. Three-dimensional graphite is obtained by stacking graphens. Therefore, the graphite sheet 1m has a high thermal conductivity in the planar direction (a two-dimensional direction), and the thermal conductivity of the wiring board 1 is increased by using the characteristics of the graphite sheet 1m. Meanwhile, the graphite sheet 1m is weak in mechanical strength in a vertical direction (i.e., can be easily bent). Therefore, in this first embodiment, the mechanical strength in the vertical direction can be increased by laminating the graphite sheet 1m and the metal layer 1n.

An example of a suitable material for the graphite sheet 1m is highly oriented pyrolytic graphite.

Here, problems studied by the inventors of the present application are described in detail.

Graphite materials have thickness-dependent characteristics that thermal conductivity thereof is higher as its thickness is thinner. The reason is that when the film thickness is thick, a heat capacity is generated and lowers the thermal conductivity. When being compared with a copper film, for example, a graphite film having a thickness of less than 40 μm usually has a thermal conductivity that is three to four times that of a copper film. However, in a case of using a graphite film that is as thick as about 100 μm, the thermal conductivity of a copper film is higher than that of the graphite film, and therefore there is no advantage of using graphite materials.

For this reason, in case of using a graphite material, an effect of increasing the thermal conductivity is larger as the thickness is thinner. Further, a thin film extending in a planar direction of a substrate is effective as measures for diffusing heat in the substrate, because a heat-source density is increased as semiconductor and a problem of Joule heat is generated. However, graphite materials are not resistant to softening in the planar direction. In other words, there is a problem that graphite materials can be easily bent by stress in the vertical direction, whereas they are strong against stress (compression or tension) in the planar direction. The characteristics of the graphite materials of being easily bendable may be described as being low in mobility.

Therefore, in the wiring board 1 of this first embodiment, the graphite sheet 1m and the metal layer 1n are laminated, so that the thermal conductivity is increased by use of the thin graphite sheet 1m, and the mechanical strength is ensured by the metal layer 1n to reduce occurrence of a crack that can easily occur in graphite. Also, even if the crack is formed in the graphite sheet 1m, it is possible to complement the crack by the metal layer 1n.

In other words, the wiring board 1 of this first embodiment complements mechanical fragility and poor workability, which are characteristics of graphite materials that are carbon materials, by the metal layer 1n and has both an advantage of graphite materials and an advantage of the metal layer 1n simultaneously. More specifically, by connecting a bent portion (a portion where a crack is formed) of the graphite sheet 1m because of weakness of graphite materials against stress in the vertical direction by the metal layer 1n as a continuous film, it is possible to connect and improve diffusion of heat in the planar direction without disconnection, and to increase thermal conduction in the wiring board 1.

Features of respective layers of the wiring board 1 are described here.

The metal layer 1n is made of an alloy that mainly contains copper (Cu), aluminum (Al), nickel (Ni), gold (Au), silver (Ag) or palladium (Pd), for example. In this first embodiment, a case where the metal layer 1n is a copper layer is described.

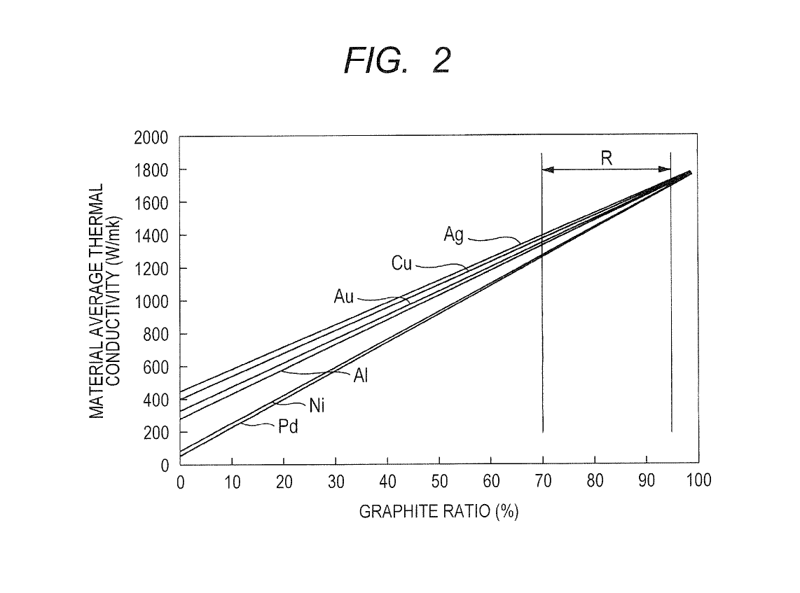

FIG. 2 is a line chart illustrating examples of a relation between a graphite ratio and a thermal conductivity when various metal materials are used.

In basic characteristics of the electrically conducting layer 1p formed by the metal layer 1n and the graphite sheet 1m, the thermal conductivity increases linearly from a value unique to a metal with increase of the graphite ratio, as illustrated in FIG. 2. With regard to thermal conduction, it is desirable that an efficiency is improved by hopping conduction (a phenomenon in which thermal conduction becomes better via a metal at an accelerated pace). Therefore, it is preferable to use a portion where these linear characteristics shift from graphite characteristics toward metal characteristics, more specifically, a region providing better thermal conduction in which the graphite ratio is 70% or more, that is, the amount of metal is less (a metal ratio is less than 30%). However, the metal ratio cannot be set to 0%. Therefore, an upper limit of the graphite ratio is set to about 95%. That is, it is preferable to apply a range R where the graphite ratio is 70% to 95% illustrated in FIG. 2.

For example, in a case where the metal layer 1n is a copper layer, a limit of a thickness of the copper layer is described. In general, when the copper layer is thinner than 500 angstroms (0.05 μm), a cohesion temperature becomes lower, so that a continuous film of a metal (a copper layer) cannot be maintained by a heat process at a temperature of about 200 degrees. Therefore, in case where the metal layer 1n is a copper layer, it is preferable that the copper layer has a thickness of 500 angstroms or more. An upper limit of the physical thickness of the copper layer is about 25 μm or less, because the thickness of the wiring board 1 including a four-layered wiring layer is 100 μm, for example. The thickness of the graphite sheet 1m is less than 10 μm, preferably, about 1 μm, for example. The line of the copper (Cu) layer in FIG. 2 represents a case where the thickness of a lamination of the graphite sheet 1m and the metal layer 1n (copper layer) is 1 μm. For example, the thickness of the copper layer is 500 angstroms (0.05 μm) for the graphite sheet 1m having a thickness of 0.95 μm, and the graphite ratio in that case is 95%.

Further, it is preferable that the thickness of the metal layer 1n is thinner than that of the graphite sheet 1m. By making the thickness of the metal layer 1n thinner than that of the graphite sheet 1m, the weight of the wiring board 1 can be reduced.

In addition, in the wiring board 1 of this first embodiment, the electrically conducting layer 1p is a lamination of the graphite sheet 1m and the metal layers (copper layers) 1n arranged above and below the graphite sheet 1m. With this structure, an effect of complementing the disadvantage of the graphite sheet 1m by the metal layer 1n can be doubled. In other words, while the thermal conductivity is increased by the thin graphite sheet 1m in the electrically conducting layer 1p, it is possible to sufficiently complement the mechanical fragility of the graphite sheet 1m by the metal layers 1n arranged above and below the graphite sheet 1m.

Furthermore, in the wiring board 1, each of the resin layer 1j and the resin layer 1k includes an insulation layer is of a glass cloth or aramid non-woven fabric, for example, as illustrated in FIG. 10. That is, the insulation layer is of glass cloth or aramid non-woven fabric, for example, is included in each of the resin layer 1j and the resin layer 1k respectively arranged above and below the electrically conducting layer 1p. More specifically, each of the resin layer 1j and the resin layer 1k is formed by the insulation layer is of glass cloth, aramid non-woven fabric, or the like, and epoxy resin-based adhesive layers 1t serving as an adhesive, arranged above and below the insulation layer 1s.

With this structure, the electrically conducting layer 1p formed by the graphite sheet 1m and the metal layer 1n is sandwiched between the resin layer 1j and the resin layer 1k each including the insulation layer 1s. Therefore, it is possible to ensure insulation of the electrically conducting layer 1p in a laminating direction (a direction of a substrate thickness).

Further, in the wiring board 1, the insulation layer (the second insulation layer) 1f that is a resin column arranged in the vicinity of each via wiring 1i includes an insulating filler. This can enhance an insulating property of the insulation layer 1f, so that it is possible to ensure insulation of each via wiring 1i with respect to the electrically conducting layer 1p.

In addition, in the wiring board 1, the insulation layer (the first insulation layer) 1e is sandwiched between insulation layers 1q that are third insulation layers having lower hardness than a resin as a main component of each of the insulation layer 1j and the insulation layer 1k. For example, in case where the resin layer 1q is made of a resin containing an inorganic insulating filler such as silica, silicone resin, or the like and the resin as the main component of each of the resin layer 1j and the resin layer 1k is an epoxy resin, the resin layer 1q is lower in hardness than the resin layers 1j and 1k.

In other words, due to an arrangement in which the insulation layer 1e including the electrically conducting layer 1p provided with the graphite sheet 1m is sandwiched between the resin layers 1q having less hardness, it is possible to buffer the mechanical fragility of the graphite sheet 1m.

Next, a manufacturing method (assembly) of the BGA 5 of this first embodiment is described.

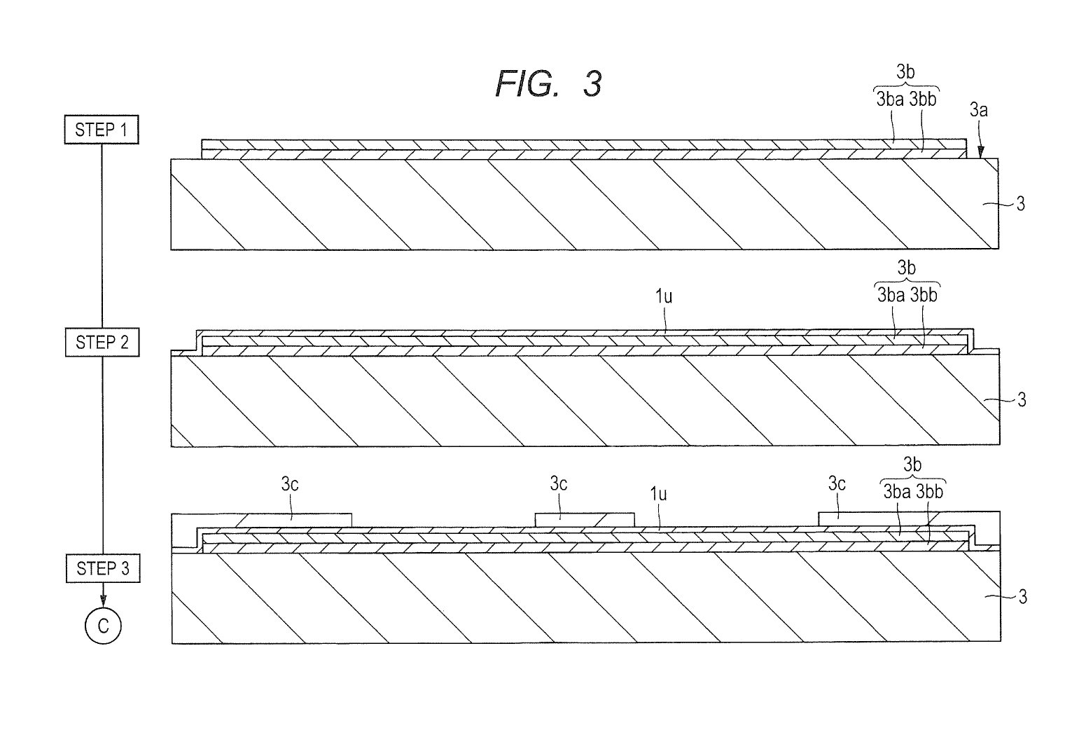

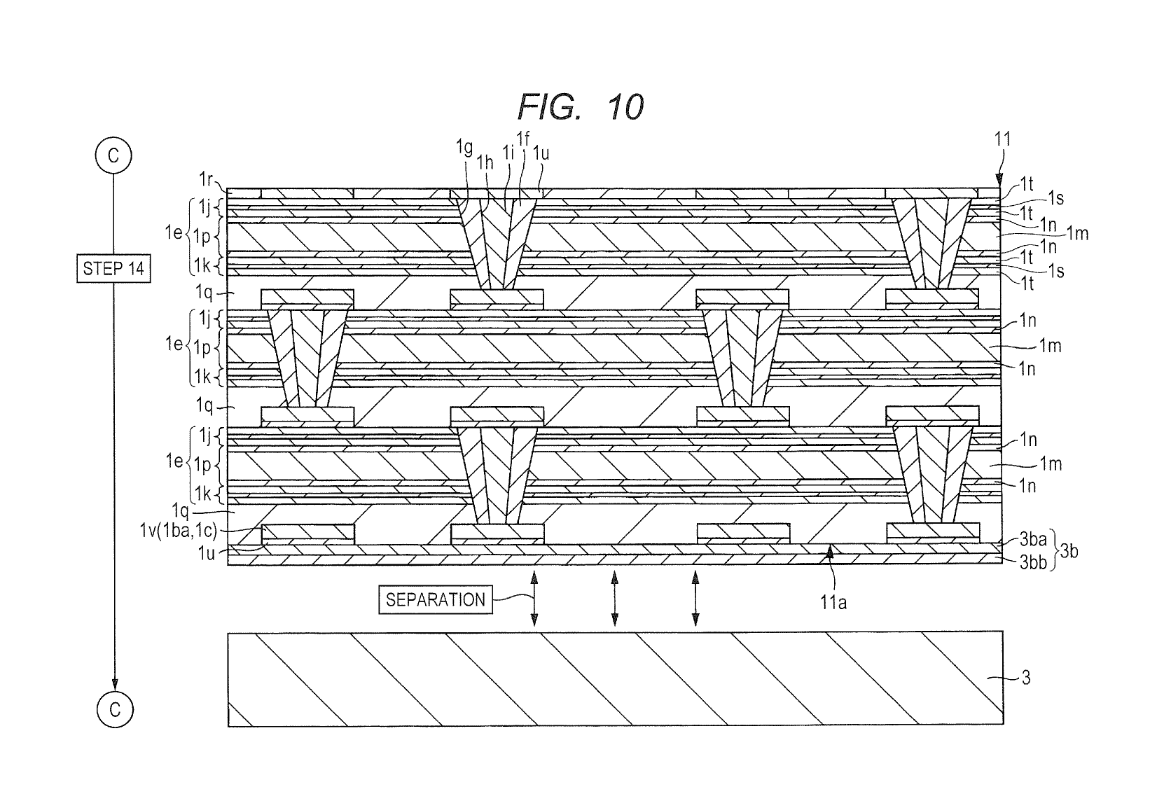

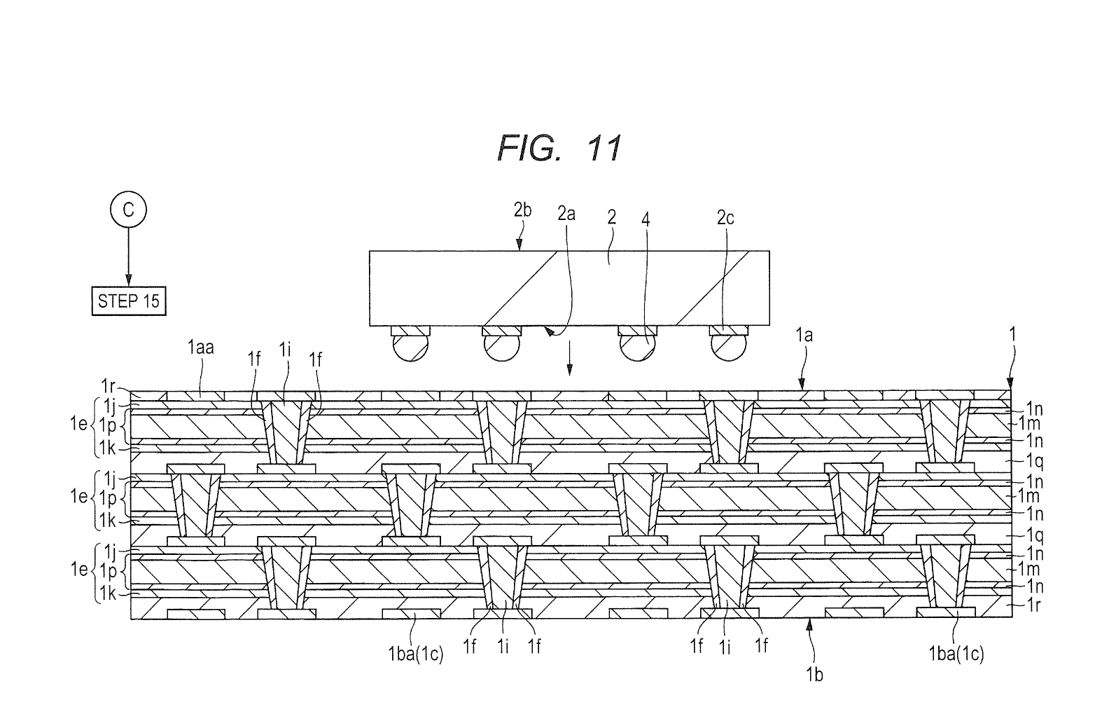

FIGS. 3 to 10 are partial cross-sectional views illustrating an example of manufacturing steps of a wiring board incorporated in the semiconductor device illustrated in FIG. 1, and FIG. 11 is a partial cross-sectional view illustrating an example of a step of mounting a semiconductor chip onto the wiring board illustrated in FIG. 10.

This manufacturing method is described by illustrating only a portion (a main portion) of the wiring board 1 for making the substrate structure easier to understand.

First, as illustrated in Step 1 in FIG. 1, a peeling layer 3b is bonded to an upper surface 3a of a supporting substrate 3. The peeling layer 3b is formed by a metal oxide film 3ba containing tungsten and a Co—Mo film 3bb, for example. The supporting substrate 3 is prepreg, and is a build-up supporting member made of copper or the like. The supporting substrate 3 has a thickness of 100 μm, the metal oxide film 3ba has a thickness of 20 μm, and the Co—Mo film 3bb has a thickness of 5 μm, for example.

After Step 1, a film-like copper thin film 1u that serves as a seed layer for plating is formed on the peeling layer 3b arranged on the supporting substrate 3 and on the upper surface 3a of the supporting substrate 3 (see Step 1 in FIG. 3), as illustrated in Step 2 in FIG. 3. The thickness of the copper thin film 1u is 12 to 18 μm, for example.

After Step 2, a resist 3c having an opening is formed on the copper thin film 1u, as illustrated in Step 3 in FIG. 3. In this step, first, the resist 3c is formed on the copper thin film 1u, and thereafter a desired portion (a portion where a wiring pattern is formed) of the resist 3c is removed by etching. That is, the opening is formed at the desired portion of the resist 3c by lithography.

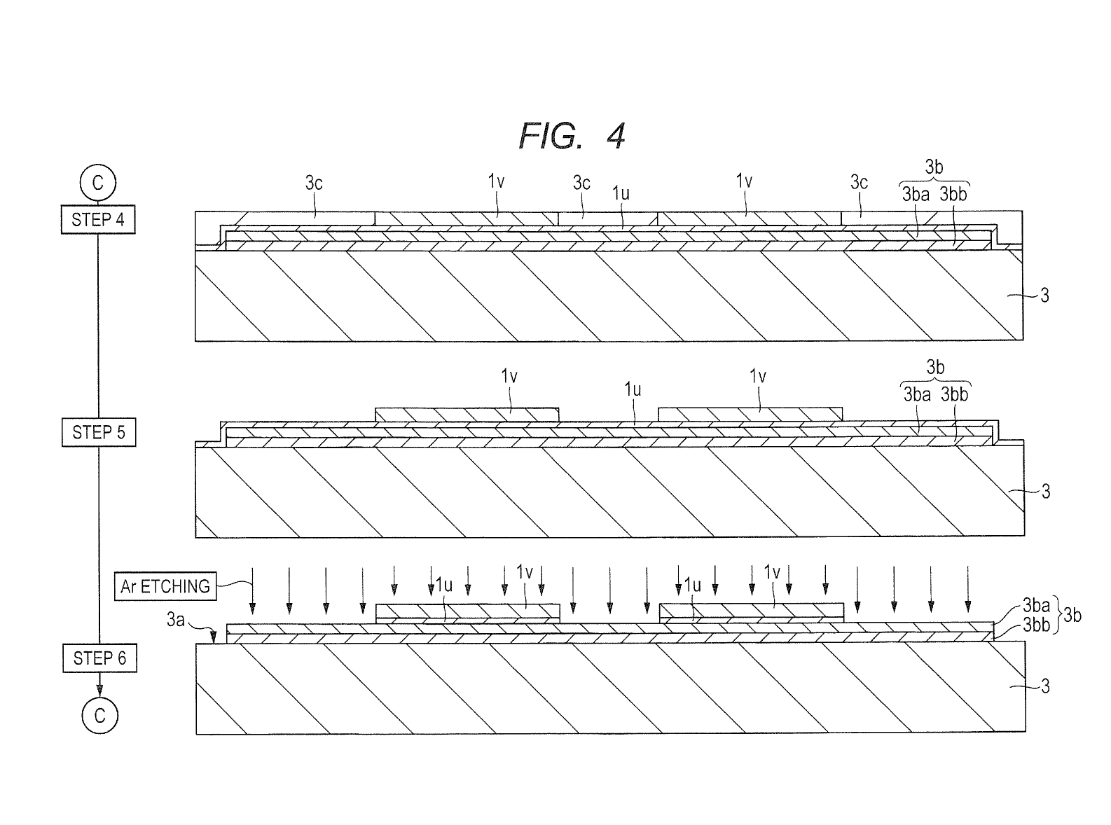

After Step 3, plating power supply (Ni electroplating) is performed by using the copper thin film 1u as the seed layer to form a wiring pattern formed by a copper pattern 1v in the opening of the resist 3c, as illustrated in Step 4 in FIG. 4.

After Step 4, the resist 3c is removed by wet etching in such a manner that the copper pattern 1v remains on the copper thin film 1u, as illustrated in Step 5 in FIG. 4.

After Step 5, etching using Ar is performed to remove the exposed copper thin film 1u, as illustrated in Step 6 in FIG. 4. In this step, etching by Ar is performed with the copper pattern 1v used as mask to remove the copper thin film 1u that is unnecessary. Because the copper pattern 1v is also etched by etching by Ar in this step, the thickness of the copper pattern 1v is reduced by about 10 μm. By the above steps, the wiring layer (the first wiring layer) 1c illustrated in FIG. 1 having the copper pattern 1v is formed on the upper surface 3a of the supporting substrate 3.

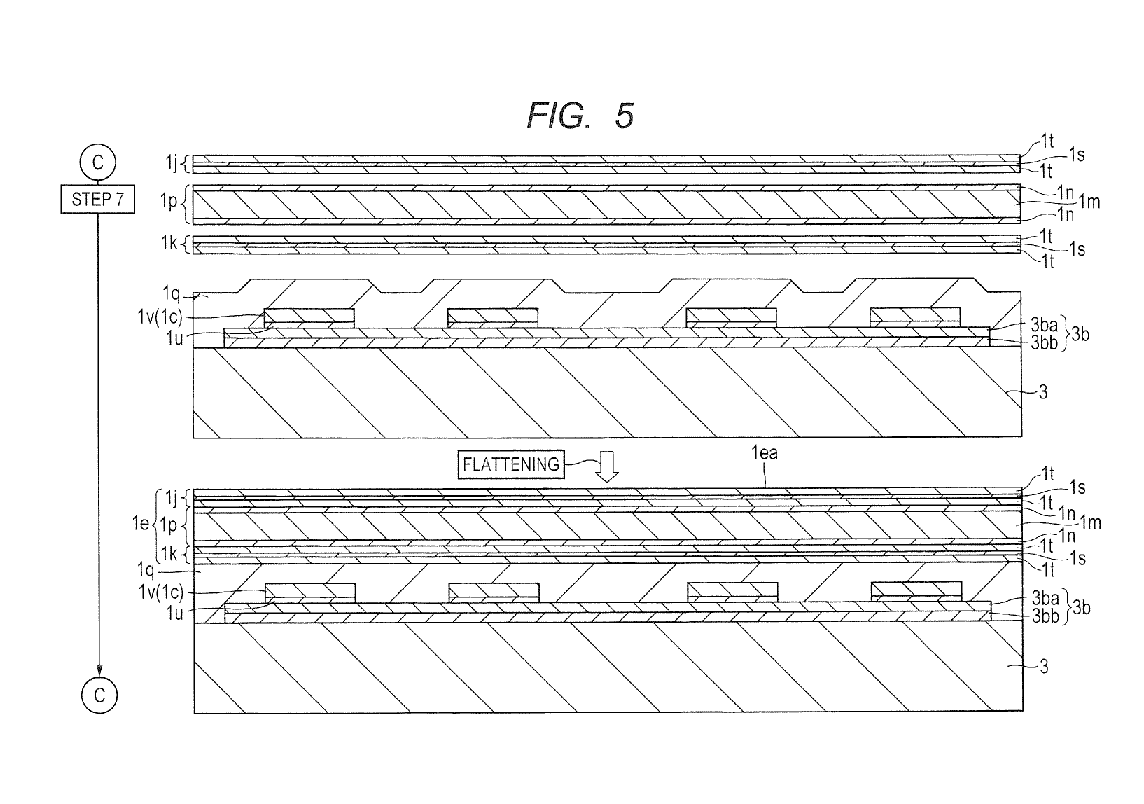

After Step 6, the resin layer 1q that is the third resin layer is formed on the copper pattern 1v (the wiring layer 1c), as illustrated in Step 7 in FIG. 5. For example, the resin layer 1q is formed by printing a resin paste in which an inorganic insulating filler, e.g., silica, is contained in a thermosetting resin, e.g., an epoxy resin. A silicone resin may be used as the resin layer 1q, for example.

After formation of the resin layer 1q, the electrically conducting layer 1p, formed by the graphite sheet 1m and the metal layers 1n and prepared in advance, is sandwiched between the resin layer 1j and the resin layer 1k to form the insulation layer 1e, and then the insulation layer 1e is arranged on the resin layer 1q. Here, the electrically conducting layer 1p is a lamination formed by sandwiching the graphite sheet 1m between the metal layers 1n each formed by a copper layer. The thickness of the metal layer 1n in the electrically conducting layer 1p is thinner than that of the graphite sheet 1m.

Further, a structure formed by sandwiching this electrically conducting layer 1p between the resin layer 1j and the resin layer 1k is the insulation layer 1e.

Each of the resin layer 1j and the resin layer 1k includes the insulation layer is of glass cloth, aramid non-woven fabric, or the like. More specifically, each of the resin layer 1j and the resin layer 1k is formed by the insulation layer is of glass cloth, aramid non-woven fabric, or the like, and the epoxy resin-based adhesive layers 1t each serving as an adhesive arranged above and below the insulation layer 1s.

As described above, the electrically conducting layer 1p is arranged on the resin layer 1q, while being sandwiched between the resin layer 1j and the resin layer 1k. Thereafter, a heat treatment and a rolling treatment are performed to bond the respective resins to each other, harden the resins, and flatten an upper surface lea of the insulation layer 1e. A temperature of the heat treatment is 150° C., for example.

By the above steps, the insulation layer 1e, formed by the resin layer 1j, the resin layer 1k, and the electrically conducting layer 1p arranged between the resin layer 1j and the resin layer 1k, is formed on the resin layer 1q on the wiring layer 1c.

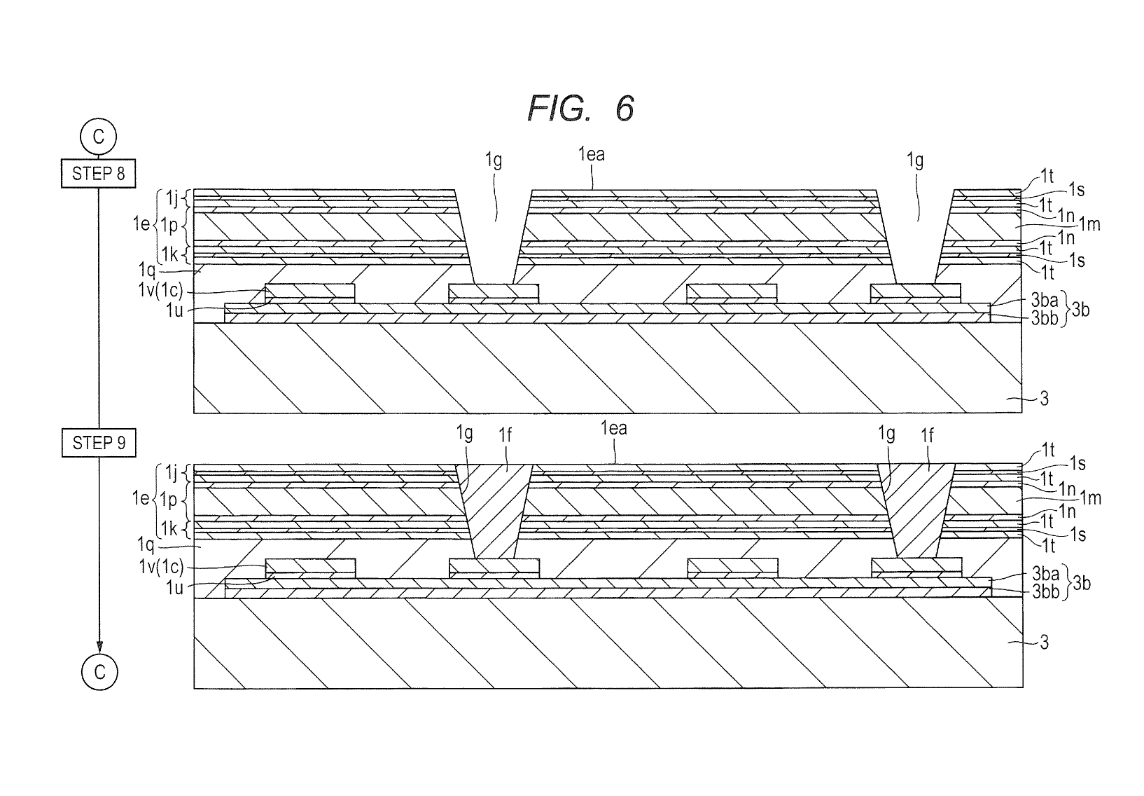

After Step 7, the hole (the first hole) 1g extending through the insulation layer 1e is formed, as illustrated in Step 8 in FIG. 6. In this example, the hole 1g is formed in a desired copper pattern 1v by radiating laser, for example. In the radiation, a laser power is set considering reflection of the laser.

After Step 8, the insulation layer (the second insulation layer) 1f is formed in each hole 1g, as illustrated in Step 9 in FIG. 6. In this example, the inside of the hole 1g is filled with the insulation layer (the second insulation layer) 1f that is a resin column in which an inorganic insulating filler is contained in a thermosetting resin, by screen printing, and thereafter the insulation film 1f is thermoset.

After the thermosetting, an upper portion of the insulation layer 1f is polished to flatten the upper surface lea of the insulation layer 1e in such a manner that the upper portion of the insulation layer 1f and the upper surface lea of the insulation layer 1e are in the same plane. Flattening of the upper surface lea of the insulation layer 1e by polishing the upper portion of the insulation layer 1f is carried out by using a polishing device that performs buffing, for example.

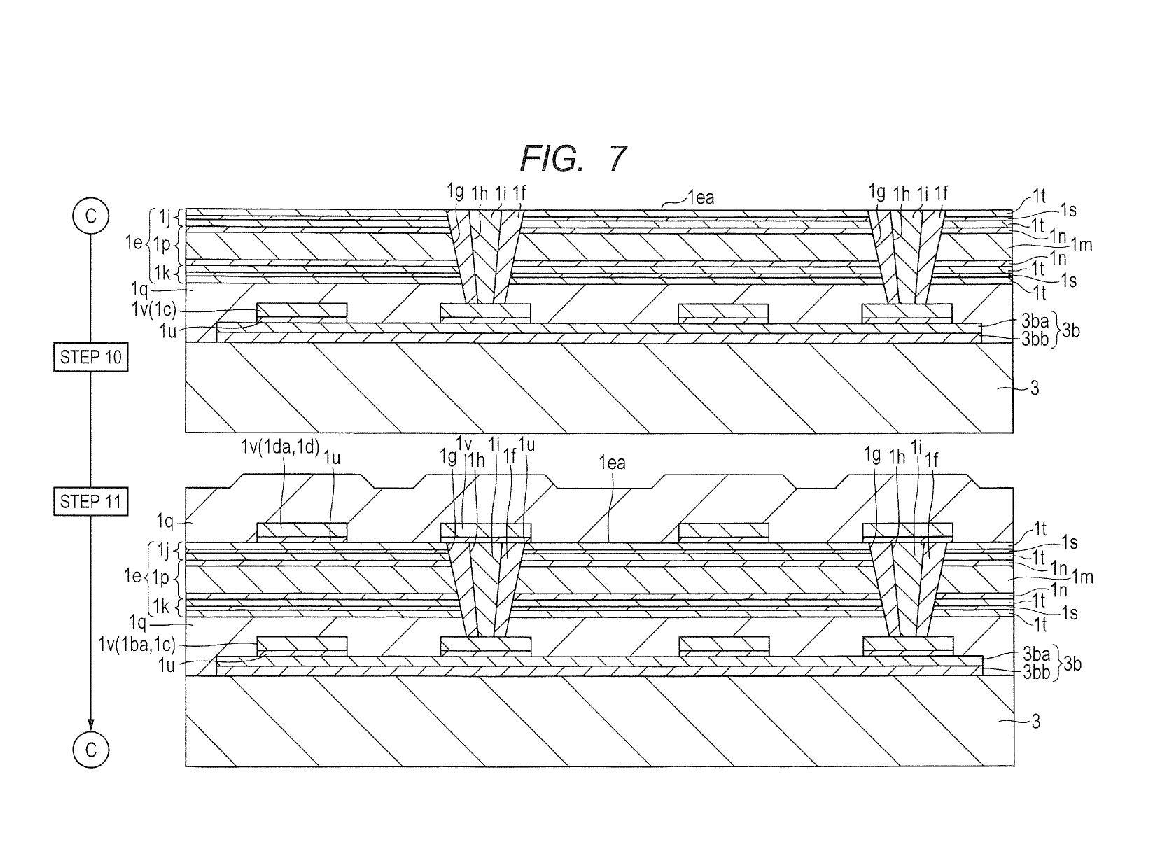

After Step 9, the hole (the second hole) 1h extending through the insulation layer 1f is formed in the insulation layer 1f that is the resin column, and the via wiring (wiring) 1i is formed in this hole 1h, as illustrated in Step 10 in FIG. 7. That is, the hole 1h having a diameter of 50 to 200 μm is formed in the insulation layer 1f located above the copper pattern 1v by using laser. A surface of the insulation layer 1f and an inner surface of the hole 1h are then chemically roughened, for example, by a roughening agent, e.g., a potassium permanganate solution, and thereafter the via wiring 1i is formed in the hole 1h by plating.

After Step 10, the land (the conductor portion, the wiring pattern, the copper pattern) 1da of the wiring layer (the second wiring layer) 1d is formed by plating on the upper surface lea of the insulation layer 1e by using a semi-additive process, as illustrated in Step 11 in FIG. 7.

By this step, the land (conductor portion, wiring pattern, copper pattern) 1ba of the wiring layer (the first wiring layer) 1c and the land (conductor portion, wiring pattern, copper pattern) 1da of the wiring layer (the second wiring layer) 1d are electrically coupled to each other by the via wiring 1i formed in the hole 1h.

After formation of the wiring layer 1d, the resin layer 1q that is the third resin layer is formed on the wiring layer 1d by printing or the like.

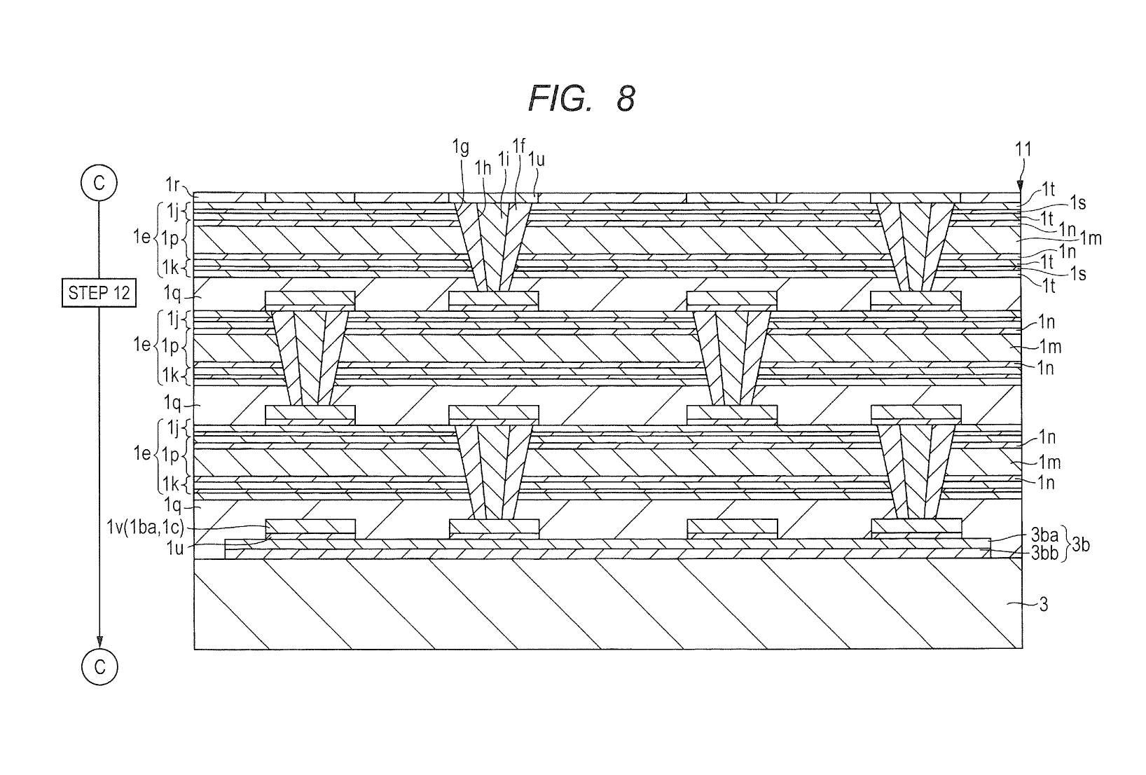

After Step 11, formation of the insulation layer 1e on the resin layer 1q, formation of the insulation layer 1f and the via wiring 1i in the hole 1g extending through the insulation layer 1e, and the like are repeated a plurality of times to manufacture a build-up substrate 11, as illustrated in Step 12 in FIG. 8.

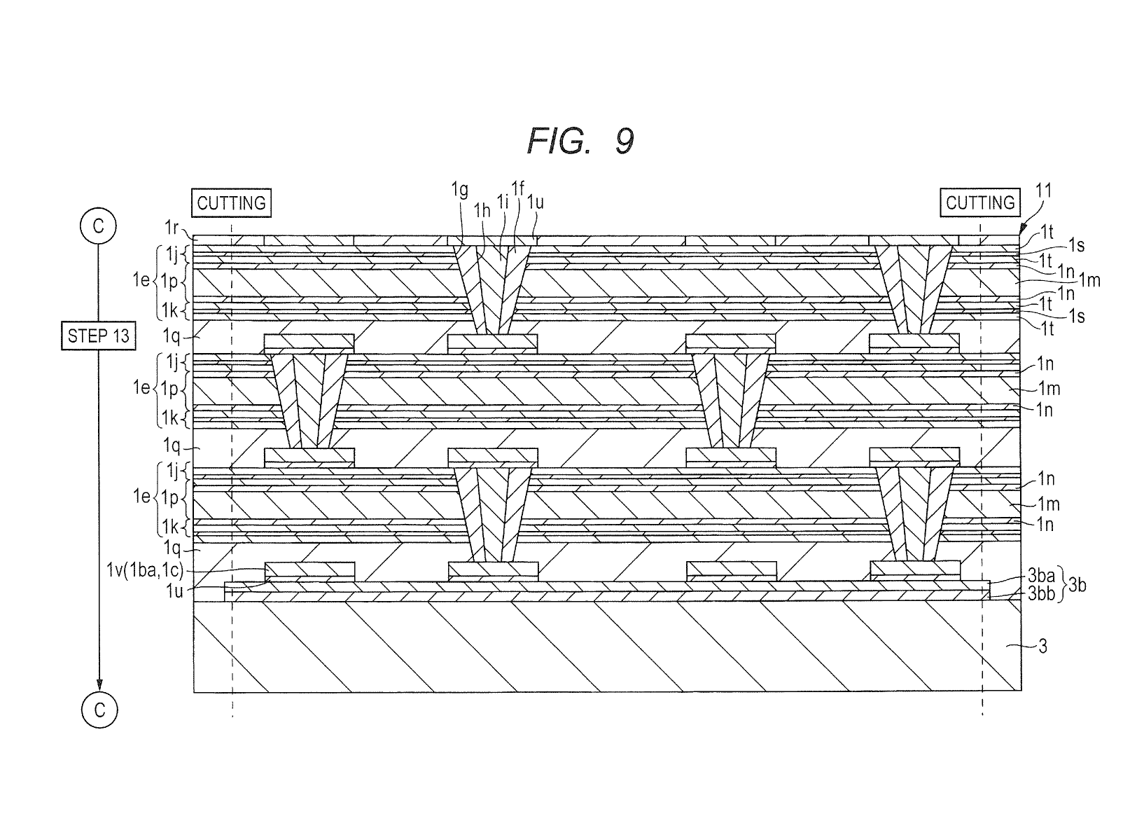

After Step 12, cutting is performed at a predetermined position in a peripheral portion of the substrate in such a manner that the peeling layer 3b located between the supporting substrate 3 and the build-up substrate 11 is exposed, as illustrated in Step 13 in FIG. 9.

After Step 13, the supporting substrate 3 and the lower surface 11a including the copper pattern 1v (the wiring layer 1c) of the build-up substrate 11 are separated from each other via the peeling layer 3b bonded to the lower surface 11a, as illustrated in Step 14 in FIG. 10. More specifically, the supporting substrate 3 and the peeling layer 3b bonded to the lower surface 11a of the build-up substrate 11 are separated from each other by being mechanically pulled, for example.

After the separation, the peeling layer 3b of the build-up substrate 11 is peeled off from the build-up substrate 11 by being immersed in a peeling agent or application of the peeling agent onto the peeling layer 3b, for example. The peeling agent used in this step is alkali metal hydroxide, for example.

By the above steps, the wiring board 1 having the upper surface (the first surface) 1a and the lower surface (the second surface) 1b illustrated in FIG. 1 is manufactured.

After Step 14, the semiconductor chip 2 is mounted on the upper surface 1a of the wiring board 1, as illustrated in Step 15 in FIG. 11. Because flip-chip mounting is performed in this example, the semiconductor chip 2 is mounted on the upper surface 1a of the wiring board 1 via a plurality of bump electrodes 4. More specifically, the semiconductor chip 2 is mounted by coupling the bump electrode 4 provided on the electrode pad 2c of the semiconductor chip 2 to the land 1aa of the upper surface 1a of the wiring board 1 so that the semiconductor chip 2 and the wiring board 1 are electrically coupled to each other via each of the bump electrodes 4.

In flip-chip mounting, the semiconductor chip 2 is mounted while a space between the wiring board 1 and the semiconductor chip 2 is filled with the underfill 6 illustrated in FIG. 1 that is arranged in advance on the upper surface 1a, for example. Alternatively, after flip-chip mounting of the semiconductor chip 2 via the bump electrodes 4, the space between the wiring board 1 and the semiconductor chip 2 is filled with the underfill 6.

After mounting of the semiconductor chip, the lid 7 illustrated in FIG. 1 is attached on the semiconductor chip 2 via the electrically conducting adhesive 9 and the adhesive 10.

After the lid 7 is attached, the ball electrode 8 that is an external terminal is mounted on each of the lands (electrodes) 1ba provided on the lower surface 1b of the wiring board 1.

With this step, the assembly of the BGA 5 illustrated in FIG. 1 is completed.

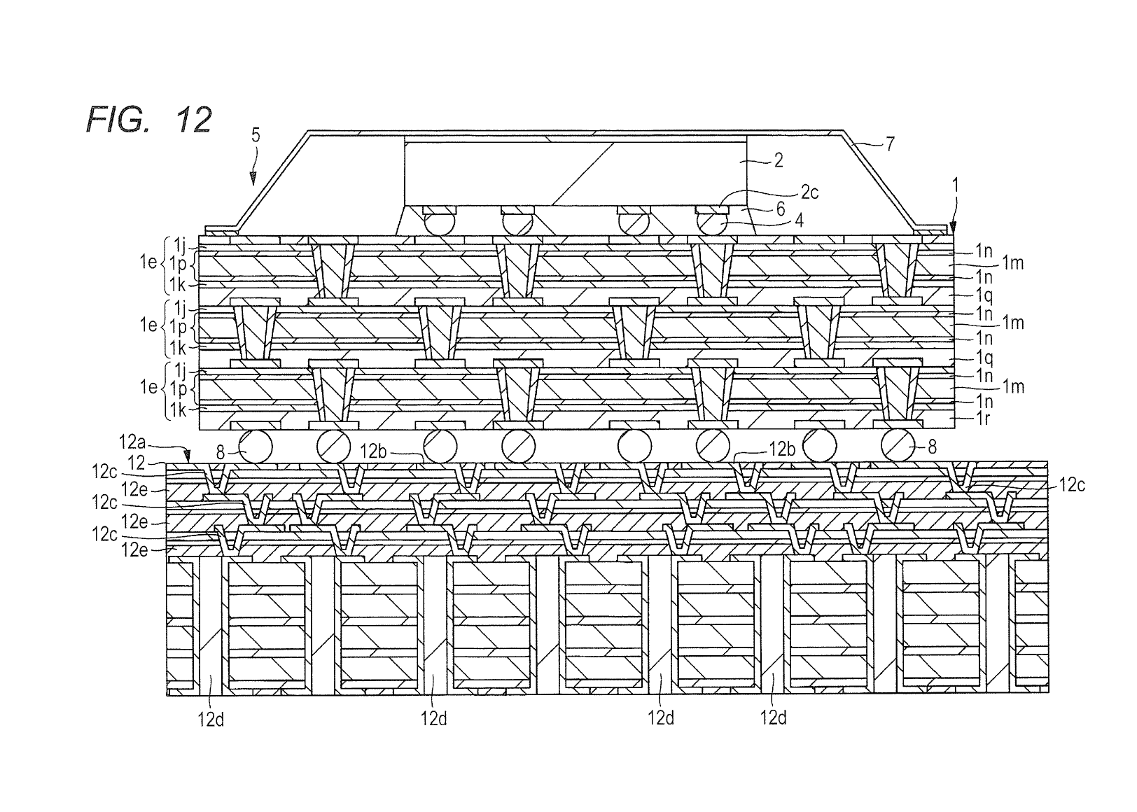

Next, a mounting structure of the BGA 5 is described. FIG. 12 is a partial cross-sectional view illustrating an example of the mounting structure of the semiconductor device illustrated in FIG. 1.

The structure illustrated in FIG. 12 is that in a case where a mounting substrate 12 is a semiconductor substrate, for example, and is an example of a structure in which the BGA 5 is mounted on the above semiconductor substrate. The mounting substrate 12 has a plurality of through electrodes 12d. A plurality of vias 12c are formed in an interlayer insulation film 12e that is a layer above the through electrodes 12d. Each of lands 12b on an upper surface 12a of the mounting substrate 12 is electrically coupled to a corresponding one of the through electrodes 12d via the vias 12c.

The BGA 5 is coupled to each of the lands 12b of the mounting substrate 12 by solder via the ball electrode (a solder ball) 8 that is the external terminal.

According to the BGA 5 of this first embodiment, it is possible to improve thermal conductivity in the wiring board 1 incorporated into the BGA 5. More specifically, by laminating the graphite sheet 1m and the metal layer 1n in the wiring board 1, it is possible to increase the thermal conductivity while the strength of the wiring board 1 is ensured.

More specifically, as compared with a case of a single-layered graphite material, the graphite sheet 1m can be formed to be thin. Therefore, it is possible to achieve a multilayered substrate with an improved thermal conductivity. Further, by laminating the metal layer 1n having a high mobility that complements a disadvantage of graphite materials, i.e., a low mobility, it is possible to complement the strength of the graphite sheet 1m by the metal layer 1n laminated on the graphite sheet 1m even if a crack is formed in the graphite sheet 1m.

In other words, mechanical fragility and poor workability that are characteristics of graphite materials that are carbon materials are complemented by the metal layer 1n. Thus, the electrically conducting layer 1p of this first embodiment has both an advantage of the graphite material and an advantage of the metal layer 1n simultaneously. That is, because the graphite material is weak against stress in the vertical direction, it is possible to connect and improve diffusion of heat in the planar direction without disconnection by connecting a bent portion (a portion where a crack is formed) of the graphite sheet 1m with a continuous film that is the metal layer 1n, so that thermal conduction of the wiring board 1 can be increased.

That is, while features of a light weight and a high thermal conductivity, that are advantages of carbon materials (graphite materials) are used, it is possible to achieve a structure in which a mechanically weak portion is complemented by the metal layer 1n.

In addition, by employing a laminating structure in which the graphite sheet 1m is sandwiched between the metal layers 1n arranged above and below the graphite sheet 1m in the electrically conducting layer 1p as in the structure of this first embodiment, it is possible to enhance an effect of complementing mechanical fragility and poor workability of graphite materials. That is, the structure in which the graphite sheet 1m is sandwiched between the metal layers 1n can improve the mechanical strength and the workability of graphite materials.

### Second Embodiment

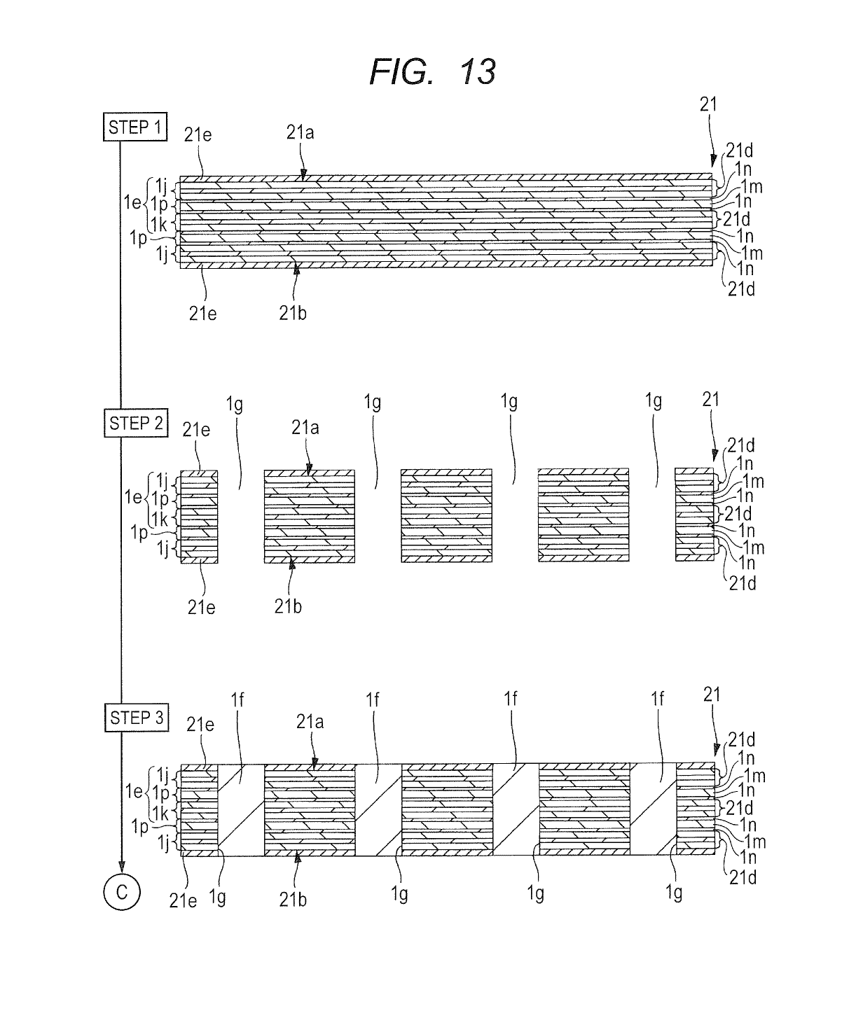

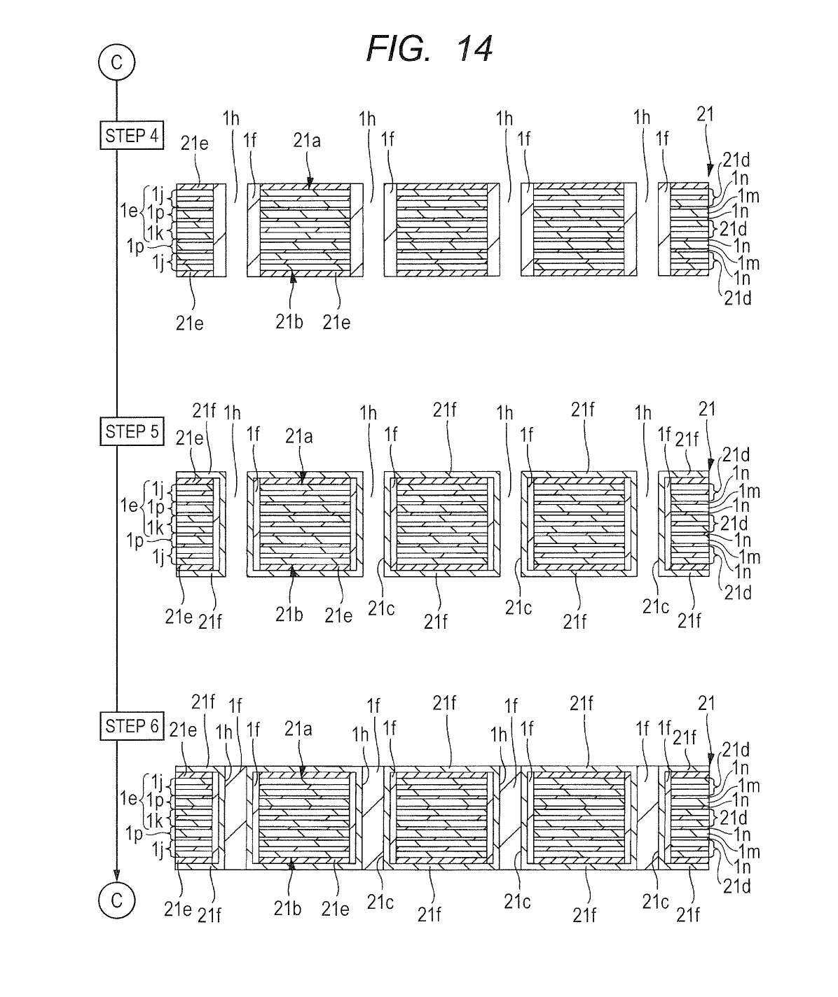

FIG. 13 is a partial cross-sectional view illustrating an example of manufacturing steps of a core substrate according to a second embodiment, FIG. 14 is a partial cross-sectional view illustrating an example of manufacturing steps of the core substrate according to the second embodiment, and FIG. 15 is a partial cross-sectional view illustrating an example of a manufacturing step of the core substrate according to the second embodiment.

In this second embodiment, an example is described in which a lamination of a graphite material and a metal layer is employed in the core substrate. A wiring board of this second embodiment is formed by repeating formation of a core substrate 21. A case is described in which the electrically conducting layer 1p is a lamination of the graphite sheet 1m and the metal layers 1n and the graphite sheet 1m is sandwiched between the metal layers 1n, as in the wiring board 1 of the first embodiment. Further, a case where the metal layer 1n is a copper layer as in the first embodiment is described.

In the core substrate 21 illustrated in FIG. 15, the electrically conducting layer 1p including the graphite sheet 1m, and the resin layer 1j or the resin layer 1k are alternately arranged in a laminating direction. In the core substrate 21, a through wiring (a through conductor) 21c is provided to extend through the core substrate 21 from an upper surface 21a to a lower surface 21b (or from the lower surface 21b to the upper surface 21a). The through wiring 21c is formed to be cylindrical by plating or the like, and electrically couples a land 21aa of the wiring layer 1d formed on the upper surface 21a side and a land 21ba of the wiring layer 1c formed on the lower surface 21b side to each other.

The insulation layer 1f that is the second insulation layer is formed on each of an inner side and an outer side of the cylindrical through wiring 21c. With the insulation layers 1f, the through wiring 21c, and the graphite sheet 1m and the metal layer 1n are insulated from each other.

Next, a manufacturing method of the core substrate 21 illustrated in FIG. 15 is described.

As illustrated in Step 1 in FIG. 13, an unset insulating sheet (the resin layer 1j or the resin layer 1k) 21d in which a reinforce material, e.g., glass cloth or aramid non-woven fabric, is impregnated with a thermosetting resin is alternately arranged above and below the electrically conducting layer 1p that is a laminated film of the graphite sheet 1m and the metal layers (copper layers in this example) 1n. The thermosetting resin is a resin that is heat-resistant and chemical-resistant, typified by epoxy resin and bismaleimide-triazine resin.

A copper foil 21e is bonded to the core substrate 21 on each of the upper surface 21a side and the lower surface 21b side.

After Step 1, the thermosetting resin in the insulating sheet 21d is thermally set to manufacture the core substrate 21 that is an insulating substrate and has the copper foil 21e on each of the upper surface 21a and the lower surface 21b, as illustrated in Step 2 in FIG. 13. After the above manufacturing, a plurality of holes (through holes) 1g are formed to extend through the copper foil 21e and the core substrate 21 by using a micro drill.

After Step 2, the insulation layer (the second insulation layer) 1f is formed in each hole (through hole) 1g, as illustrated in Step 3 in FIG. 13. For example, the inside of the hole 1g is filled with the insulation layer (the second insulation layer) 1f that is a resin column in which an inorganic insulating filler is contained in a thermosetting resin, by screen printing. Thereafter, the insulating layer 1f is thermally set, so that each hole 1g is closed.

After the above thermosetting, a projecting portion of the insulation layer 1f is polished so that the insulation layer 1f is flattened. The above flattening is carried out by using a polishing device that performs buffing, for example.

After Step 3, a hole (through hole) 1h is formed by using a micro drill or the like in each insulation layer 1f to extend through the insulation layer 1f, as illustrated in Step 4 in FIG. 14.

After Step 4, a tubular through wiring (a through conductor) 21c is formed (deposited) on an inner surface of the hole 1h by plating, as illustrated in Step 5 in FIG. 14. Further, a conductor film 21f is also formed (deposited) on a surface of the copper foil 21e by plating simultaneously.

After Step 5, the insulation layer (the second insulation layer) 1f is formed in each hole 1h (in the tubular through wiring 21c), as illustrated in Step 6 in FIG. 14. For example, the inside of the hole 1h is filled with the insulation layer 1f that is a resin column in which an inorganic insulating filler is contained in a thermosetting resin, by screen printing. Thereafter, the insulating layer 1f is thermally set, so that each hole 1h is closed. After the above thermosetting, a projecting portion of the insulation layer 1f is polished so that the insulation layer 1f is flattened. The above flattening is carried out by using a polishing device that performs buffing, for example.

After Step 6, etching is performed to obtain a predetermined pattern, so that the copper foil 21e and the conductor film 21f that are unnecessary are removed, as illustrated in Step 7 in FIG. 15. By the above steps, the core substrate 21 is obtained in which a land 21aa (the conductor film 21f) and a land 21ba (the conductor film 21f) are formed on the upper surface 21a and the lower surface 21b, respectively. A wiring board in which the core substrate 21 illustrated in FIG. 15 are laminated can be formed by repeating the above steps alternately.

Also in a BGA type semiconductor device assembled by using the wiring board in which the core substrate 21 illustrated in FIG. 15 is laminated, it is possible to obtain the same operations and effects as those of the BGA 5 of the first embodiment.

In the above, the invention made by the inventors of the present application has been specifically described by way of the embodiments. However, it is naturally understood that the present invention is not limited to the aforementioned embodiments, and can be changed in various ways within the scope not departing from the gist thereof.

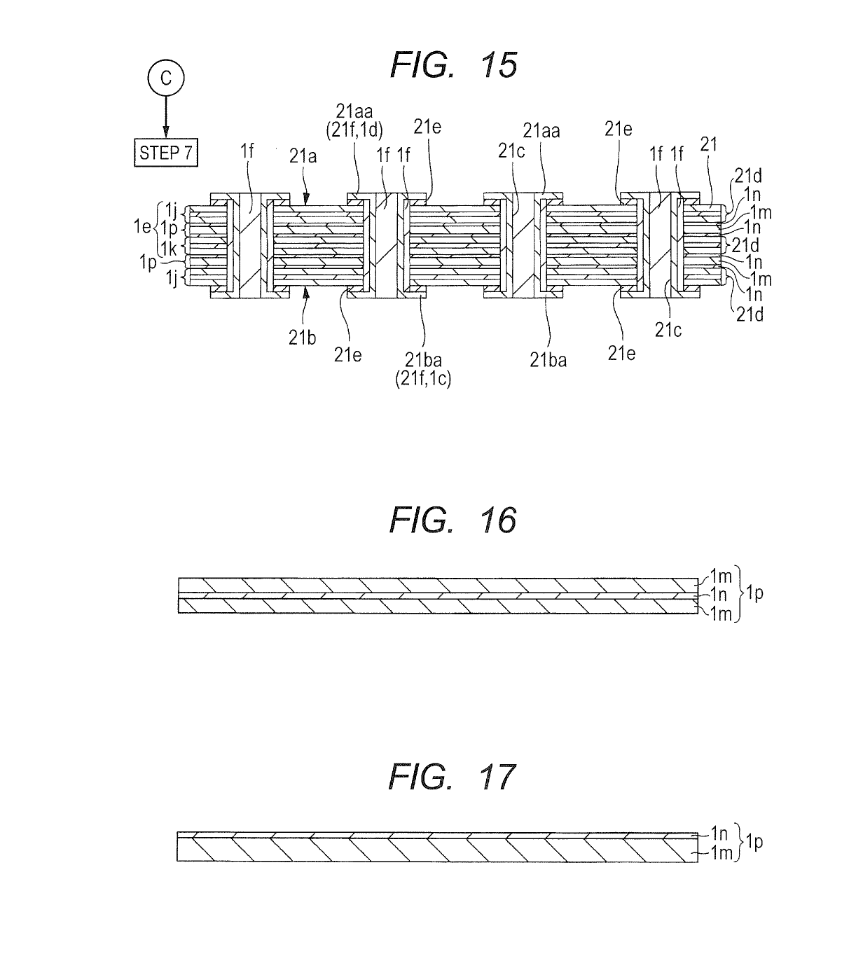

For example, although a case where the graphite sheet 1m is sandwiched between the metal layers 1n in the electrically conducting layer 1p is described in the above first and second embodiments, the metal layer 1n, such as a copper layer, may be sandwiched between the graphite sheets 1m in the electrically conducting layer 1p, as illustrated in a modified example of FIG. 16. However, the structure in which the graphite sheet 1m is sandwiched between the metal layers 1n is more preferable in light of an effect of the BGA 5 that thermal conductivity can be increased by the graphite sheet 1m while the strength of the wiring board 1 is ensured by the metal layer 1n.

Further, it is not always necessary to arrange the metal layers 1n above and below the graphite sheet 1m in the electrically conducting layer 1p. As illustrated in another modified example of FIG. 17, the metal layer 1n may be arranged on either one of an upper side and a lower side of the graphite sheet 1m. In this case, the weight of the electrically conducting layer 1p can be reduced, so that the weight of the wiring board 1 can be reduced.

In addition, although a case where the semiconductor chip 2 is mounted on the wiring board 1 via the bump electrodes 4 in the semiconductor device is described in the above first embodiment, the semiconductor device may have a structure in which the semiconductor chip 2 is electrically coupled to the wiring board 1 by wire. That is, the semiconductor device may be a wire-bonding type semiconductor device.

Furthermore, although a case where the semiconductor device is the BGA 5 is described in the above first embodiment, the semiconductor device may be another type, as long as the semiconductor chip 2 is mounted over the wiring board, for example, an LGA (Land Grid Array).

In addition, although a case where the lid 7 coupled to the semiconductor chip 2 is provided in the BGA 5 is described in the above first embodiment, the BGA 5 may be a semiconductor device in which the lid 7 is not attached.

What is claimed is:

1. A semiconductor device comprising:
a wiring board having a first surface and a second surface opposite to the first surface;
a semiconductor chip mounted over the first surface of the wiring board; and
a plurality of external terminals provided over the second surface of the wiring board,
wherein the wiring board includes
a first wiring layer,
a second wiring layer arranged over the first wiring layer,
a first insulation layer arranged between the first wiring layer and the second wiring layer,
a second insulation layer formed in a first hole extending through the first insulation layer, and
a conductor portion formed in a second hole extending through the second insulation layer to electrically couple a wiring of the first wiring layer and a wiring of the second wiring layer to each other,
wherein the first insulation layer includes a first resin layer, a second resin layer, and an electrically conducting layer arranged between the first resin layer and the second resin layer, and
wherein the electrically conducting layer includes a lamination of a graphite sheet and a metal layer.

2. The semiconductor device according to claim 1, wherein the electrically conducting layer is a lamination in which the graphite sheet is sandwiched between the metal layers.

3. The semiconductor device according to claim 1, wherein each of the first resin layer and the second resin layer includes glass cloth or aramid non-woven fabric.

4. The semiconductor device according to claim 1, wherein the first insulation layer is sandwiched between third resin layers that are lower in hardness than a resin as a main component of each of the first resin layer and the second resin layer.

5. The semiconductor device according to claim 1, wherein the electrically conducting layer having the graphite sheet and the first resin layer or the second resin layer are alternately arranged in a direction of lamination.

6. The semiconductor device according to claim 1, wherein the second insulation layer contains an insulating filler.

7. The semiconductor device according to claim 1,
wherein the metal layer is made of a copper alloy, and
wherein a thickness of the metal layer is thinner than a thickness of the graphite sheet.

8. A manufacturing method of a semiconductor device, comprising the steps of:
(a) forming a first wiring layer over a supporting substrate;
(b) after the step (a), forming a first insulation layer including a first resin layer, a second resin layer, and an electrically conducting layer arranged between the first resin layer and the second resin layer, over the first wiring layer;
(c) after the step (b), forming a first hole extending through the first insulation layer;
(d) after the step (c), forming a second insulation layer in the first hole;
(e) after the step (d), forming a second hole extending through the second insulation layer;
(f) after the step (e), forming a conductor portion in the second hole;
(g) after the step (f), forming a second wiring layer over the first insulation layer to electrically couple a wiring of the first wiring layer and a wiring of the second wiring layer to each other via the conductor portion in the second hole;
(h) after the step (g), separating the supporting substrate and the first wiring layer from each other to form a wiring board having a first surface and a second surface opposite to the first surface;
(i) after the step (h), mounting a semiconductor chip over the first surface of the wiring board; and
(j) after the step (i), providing an external terminal for each of a plurality of electrodes in the first wiring layer, wherein
the electrically conducting layer is a lamination of a graphite sheet and a metal layer.

9. The manufacturing method according to claim 8, wherein a lamination in which the graphite sheet is sandwiched between the metal layers is arranged as the electrically conducting layer.

10. The manufacturing method according to claim 8, further comprising a step of flattening an upper surface of the first insulation layer between the step (d) and the step (e).

11. The manufacturing method according to claim 8,
wherein the supporting substrate includes a peeling layer, and
wherein the supporting substrate and the first wiring layer are separated from each other via the peeling layer in the step (h).

12. The manufacturing method according to claim 8, wherein the first resin layer and the second resin layer include glass cloth or aramid non-woven fabric.

13. The manufacturing method according to claim 8, wherein the second insulation layer contains an insulating filler.

14. The manufacturing method according to claim 8, wherein
the metal layer is made of a copper alloy, and
a thickness of the metal layer is thinner than a thickness of the graphite sheet.
